(19) United States
(12) Patent Application Publication
(10) Pub. No.: US 2016/0365311 A1
(43) Pub. Date: Dec. 15, 2016

(54) METHOD OF MANUFACTURING SEMICONDUCTOR DEVICES WITH COMBINED ARRAY AND PERIPHERY PATTERNING IN SELF-ALIGNED DOUBLE PATTERNING

(71) Applicant: Macronix International Co.Ltd., Hsin-chu (TW)

(72) Inventors: Yu-Min HUNG, Taichung City (TW); Tzung-Ting HAN, Hsinchu City (TW); Miao-Chih HSU, Hsinchu City (TW)

(21) Appl. No.: 14/735,837

(22) Filed: Jun. 10, 2015

(51) Int. Cl. H01L 23/528; H01L 21/3213; H01L 27/112; H01L 21/768

(52) U.S. Cl. CPC H01L 23/528; H01L 21/76892; H01L 21/32133; H01L 21/32139; H01L 27/11293

(57) ABSTRACT

Provided are improved semiconductor memory devices and methods for manufacturing such semiconductor memory devices. A method may incorporate the patterning of the array and periphery regions in self-aligned double patterning and provide semiconductor devices resulting from the combined patterning.

### FIELD

Embodiments of the present invention generally relate to a semiconductor device, and methods of preparing the semiconductor device.

### BACKGROUND

Fabrication of an integrated circuit involves processes that can generally be categorized as deposition, patterning, and doping. With the use of these different processes complex structures having various components may be built to form the complex circuitry of a semiconductor device.

Lithography is the formation of a three-dimensional patterning on a substrate to form a pattern to the substrate. A multiplicity of lithographic procedures combined with etching and/or polishing may be performed to create a final semiconductor device.

Photolithography or optical lithography involves the use of a light sensitive polymer or a photoresist that is exposed and developed to form three-dimensional patterning on a substrate. The parts of the substrate that remain covered with the photoresist will be protected from subsequent etching, ion implantation, or certain other processing techniques.

The general sequence for a photolithography process may include the steps of preparing the substrate, applying a photoresist, prebaking, exposing, post-exposure baking, developing, and post-baking. Photoresists may be applied to the substrate by any number of techniques. Generally, it is somewhat important to establish a uniform thickness of the photoresist across the substrate. Optionally, a layer of bottom anti reflectivity coating (BARC) may be applied to the substrate prior to the application of the photoresist layer. Adhesion promoters may be typically applied to the substrate prior to application of the photoresist.

The premise behind photolithography is the change in solubility of the positive photoresist in a positive tone developer throughout certain regions of the photoresist that have been exposed to light, in the past visible light but more conventionally ultraviolet light, or some other form of radiation. The regions of exposure may be controlled, for example, with the use of a mask.

Applicant has identified deficiencies and problems associated with conventional processes for manufacturing memory devices and the resulting memory devices. For instance, in conventional manufacturing processes, the array and periphery regions must be formed separately using separate patterning steps. The resulting process is both time consuming and costly.

Through applied effort, ingenuity, and innovation, certain of these identified problems have been solved by developing solutions that are included in various embodiments of the present invention, which are described in detail below.

### SUMMARY

Embodiments of the present invention therefore provide methods of manufacturing semiconductor devices useful in the manufacture of memory devices and provide semiconductor memory devices resulting from such methods.

The present invention provides methods of manufacturing semiconductor devices at a reduced cost and with greater efficiency. In certain embodiments, the patterning of the array region and the periphery region of the semiconductor device may be combined such that one mask is used to pattern both regions. The present inventors have devised a layout for the semiconductor device that allows for the integration of array and periphery patterning. By integrating the patterning of the array region and the periphery region, the cost can be reduced and the efficiency of preparing suitable semiconductor devices can be increased.

In certain embodiments of the invention, a semiconductor device is provided comprising a substrate; a first word line pad formed on the substrate; and a second word line pad formed on the substrate, wherein a space is located between the first word line pad and the second word line pad, the space comprising a first width of the space represented by a and a second width of the space represented by b, and wherein width a is less than width b. In certain embodiments, the width b is located closer to a word line than the width a and wherein the word line connects to the first word line pad or the second word line pad. In some embodiments, the width b is about 1.5 to 3.0 times the width a, such as about 1.5 times the width a or about 3.0 times the width a. In some embodiments, the space between the first word line pad and the second word line pad may comprise a semicircle.

In some embodiments, the semiconductor device may comprise a first word line pad comprising a first pad width adjacent to a word line and a second pad width opposite the word line, wherein the first pad width is not equal to the second pad width, and wherein the word line connect to the first word line pad. In certain embodiments, the semiconductor device may comprise a second word line pad comprising a first width of the second word line pad adjacent to a word line and a second width of the second word line pad opposite the word line and wherein the first width of the second word line pad is smaller than the second width of the second word line pad. In certain embodiments, the first word line pad is a mirror image of the second word line pad.

An aspect of the invention also provides a method for manufacturing a semiconductor device comprising providing a substrate; forming a film stack along the substrate; and etching the film stack to form a first word line pad and a second word line pad with a space between the first word line pad and the second word line pad, the space comprising a first width of the space represented by a and a second width of the space represented by b, wherein a is less than b. In some embodiments, the width b is located closer to a word line than the width a and wherein the word line connects to the first word line pad or the second word line pad. In certain embodiments, the width b is about 1.5 to 3.0 times the width a, such as about 1.5 times the width a or about 3.0 times the width a. In some embodiments, the space between the first word line pad and the second word line pad forms a semicircle.

In certain embodiments of the invention, the step of etching the film stack comprises etching the first word line pad with a first pad width adjacent to a word line and a second pad width opposite the word line, wherein the first pad width is not equal to the second pad width. In one embodiment of the invention, the method for manufacturing a semiconductor device forms a second word line pad comprising a first width of the second word line pad adjacent to a word line and a second width of the second word line pad opposite the word line and wherein the first width of the second word line pad is smaller than the second width of the second word line pad.

In some embodiments, the method of manufacturing a semiconductor device further comprises forming a first hard mask layer along the film stack; forming a second hard mask layer along the first hard mask layer; forming a core layer along the second hard mask layer; patterning the core layer to form a patterned core layer; forming spacers along sidewalls of the patterned core layer; etching the second hard mask layer; removing the patterned core layer; removing portions of the second hard mask layer; and etching the first hard mask layer. In certain embodiments, removing portions of the second hard mask layer comprises removing second hard mask material in a semicircle shape in a pad pattern along the film stack. In some embodiments, the semicircle shape in the pad pattern along the film stack has a radius of about 200 to about 300 nm. Still further, in some embodiments, patterning the core layer to form a patterned core layer comprises forming a pad pattern and a word line pattern, wherein the pad pattern has a width of greater than about 600 nm and the word line pattern has a width of about 10 to about 30 nm.

The above summary is provided merely for purposes of summarizing some example embodiments of the invention so as to provide a basic understanding of some aspects of the invention. Accordingly, it will be appreciated that the above described example embodiments are merely examples and should not be construed to narrow the scope or spirit of the invention in any way. It will be appreciated that the scope of the invention encompasses many potential embodiments, some of which will be further described below, in addition to those here summarized.

### BRIEF DESCRIPTION OF THE DRAWING(S)

Having thus described the invention in general terms, reference will now be made to the accompanying drawings, which are not necessarily drawn to scale, and wherein:

FIGS. 1(a) to 1(c) illustrate cross-sectional views of portions of a semiconductor device comprising a desired circuit layout of a semiconductor device in accordance with embodiments of the present invention;

FIGS. 2(a) to 2(c) illustrate cross-sectional views of a semiconductor device after applying a photo resist to the device in accordance with embodiments of the present invention;

FIGS. 3(a) to 3(c) illustrate cross-sectional views of a semiconductor device after etching of the core material to provide a pattern on the substrate in accordance with embodiments of the present invention;

FIGS. 4(a) to 4(c) illustrate cross-sectional views of a semiconductor device after forming spacers along the sidewalls of the patterned core layer in the device in accordance with embodiments of the present invention;

FIGS. 5(a) to 5(b) illustrate cross-sectional views of a semiconductor device after etching the second hard mask layer in accordance with embodiments of the present invention;

FIGS. 6(a) to 6(b) illustrate cross-sectional views of a semiconductor device after removing core material from the semiconductor device in accordance with embodiments of the present invention;

FIGS. 7(a) to 7(c) illustrate cross-sectional views of a semiconductor device after removing certain areas of the first hard mask layer in accordance with embodiments of the present invention;

FIG. 7(d) provides a profile of the array and periphery regions of a semiconductor device after removing portions of the second hard mask layer in accordance with embodiments of the present invention;

FIGS. 8(a) to 8(c) illustrate cross-sectional views of a semiconductor device after etching the first hard mask layer in accordance with embodiments of the present invention;

FIGS. 9(a) to 9(b) illustrate cross-sectional views of a semiconductor device after etching the film stack in accordance with embodiments of the present invention;

FIGS. 10(a) to 10(c) illustrate cross-sectional views of a semiconductor device after applying a photo resist over the patterned film stack in accordance with embodiments of the present invention;

FIGS. 11(a) to 11(b) illustrate as semiconductor device after etching to form adjacent word line pads in accordance with embodiments of the present invention;

FIG. 12 illustrates the formation of a semicircle or pendulum-shaped area in word line pads in accordance with embodiments of the present invention; and

FIGS. 13(a) to 13(b) provide a flow chart detailing methods of forming semiconductor devices in accordance with embodiments of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a gate structure” includes a plurality of such gate structures.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in this specification and attached claims are approximations that can vary depending upon the desired properties sought to be obtained by the presently disclosed subject matter.

As used herein, the term “about,” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

In the semiconductor industry, there is an increased desire to reduce the cost of producing semiconductor devices such as non-volatile memory devices. The market demands smaller and cheaper devices. In the production of conventional semiconductor devices, the array and the periphery regions are patterned separately using separate masks. The use of separate process steps adds complexity and cost to the process.

There remains a need in the art for alternative memory device structures and methods of preparing those structures that allow for a reduction in cost and complexity.

The present inventors have found that by forming the layout of the device as described herein, the patterning of the array and periphery regions can be integrated. The resulting semiconductor device can be prepared at a reduced cost and with an increase in efficiency. Utilizing the process steps described herein, the patterning of the array and periphery regions can be combined and provide a suitable semiconductor device.

Non-volatile memory refers to a semiconductor device which is able to store information even when the supply of electricity is removed from the memory. Non-volatile memory includes, without limitation, Mask Read-Only Memory, Programmable Read-Only Memory, Erasable Programmable Read-Only Memory, Electrically Erasable Programmable Read-Only Memory, and Flash Memory, such as NAND and NOR devices.

As used herein, “array pattern” refers to the pattern formed within the central region or an array region of a semiconductor device. In a fully formed integrated circuit, the “array region” is typically densely populated with conducting lines and electrical devices that may include transistors and capacitors. The electrical devices may form a plurality of memory cells that are typically arranged in a grid pattern at the intersection of word lines and bit lines.

As may be used interchangeably herein, “periphery pattern” or “peripheral pattern” refers to the pattern formed in the periphery region of the semiconductor device. The “periphery region” is the area surrounding the array region. The periphery region typically includes components that support the operations of, for example, the memory cells within the array region.

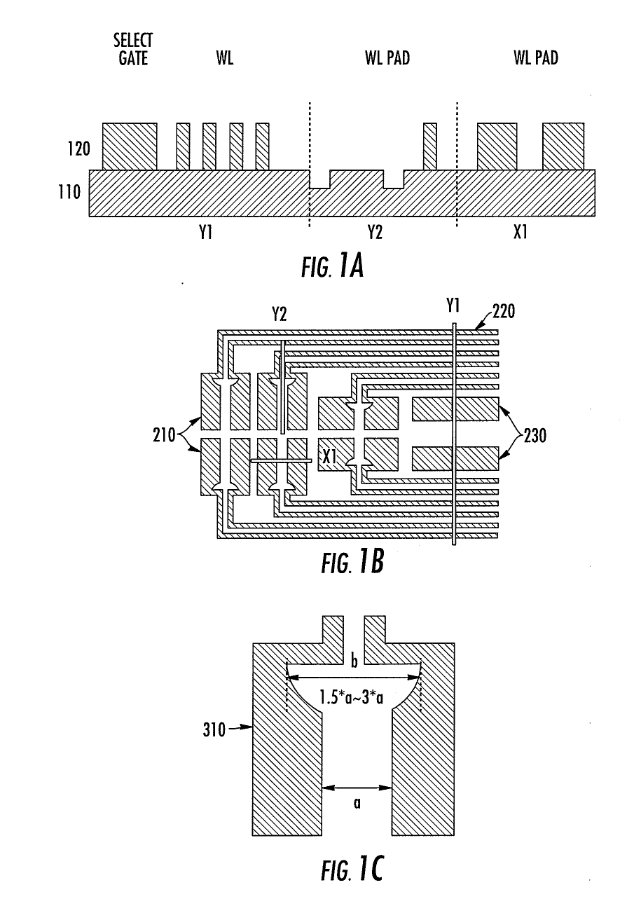

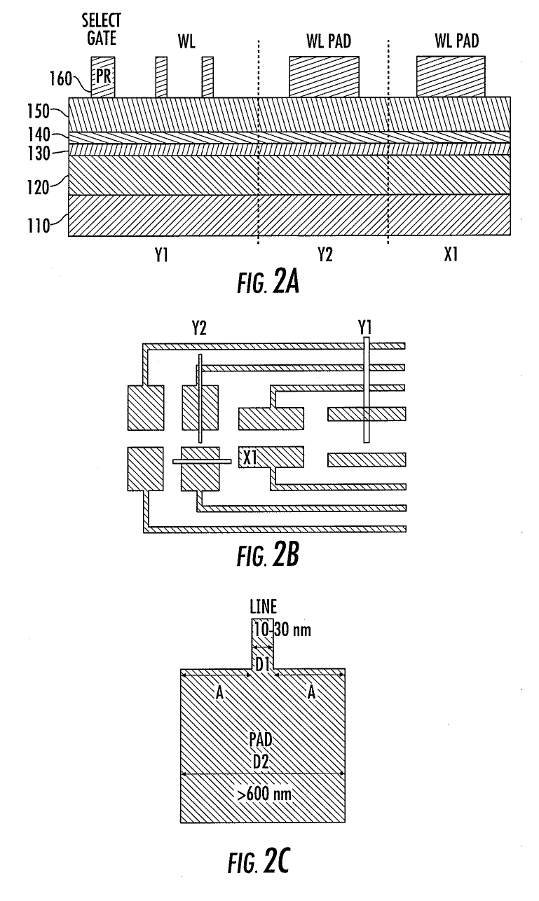

As used herein, “space” refers to the absence of one or more layers in the device such that a void is formed in the cross-section of the device. For instance, in FIG. 1(a), spaces are formed between word lines and pads.

As used here, “pad pattern” refers to a pattern formed on the semiconductor device for placement of one or more pads. As subsequent steps are performed, in the pad pattern, one or more pads may be formed. As used herein, “word line pattern” refers to a pattern formed on the semiconductor device for placement of one or more word lines. As subsequent steps are performed, in the word line pattern, one or more word lines may be formed.

As used herein, “boundary area” refers to the area around the connection point of a word line and a pad. The “connection point” refers to the location where the word line comes in contact with a pad. The word line that connects to the word line pad is referred to as the “connecting word line.” The inventors have found that, in some embodiments, by forming a certain layout of the pad and connecting word line, the patterning of the array and periphery regions can be integrated. When forming this layout, the boundary area may be etched such that further processing is made easier. The boundary area may be etched prior to formation of individual word lines or pads to enable the formation of those word lines or pads. The etching of the boundary area may create a pattern, such as a semicircle or pendulum, that may be subsequently used for patterning the desired final structure or layout of the semiconductor device. The pendulum-shape can be seen in FIG. 1, in the area between adjacent pads.

FIG. 1 illustrates cross-sectional views of portions of a semiconductor device comprising a desired circuit layout of a semiconductor device in accordance with embodiments of the present invention. FIG. 1 provides a cross section of the semiconductor device in the array region and in the periphery region. The array cross section is represented by the Y1 axis and the periphery cross section is represented by the X1 axis. The connection between the array and periphery regions is represented by the Y2 axis. The X1 axis lies across two adjacent pads. The cross sections are illustrated in FIG. 1(a) with identifying markings showing the Select Gate, Word Line (“WL”), Word Line PAD Connection (“WL PAD”), and Word Line PAD (“WL PAD”). An overview of the semiconductor illustrating the locations for each cross section is provided in FIG. 1(b). An enlarged view of two adjacent word line pads is provided in FIG. 1(c).

As shown in FIG. 1, the semiconductor device of this embodiment comprises a substrate 110 and a film stack 120. The film stack 120 has been etched to form the desired components in each of the array and periphery regions of the device. In some embodiments, the film stack may comprise an oxide hard mask layer, a control gate, an interpoly dielectric layer, a floating gate, and a tunnel oxide layer. The film stack may comprise any suitable layers in any suitable order. For instance, in some embodiments, the film stack may comprise various layers as buried diffusion oxide layer, tunnel oxide layer, floating gate, control gate, high density plasma, or combinations thereof. In some embodiments, a shallow trench isolation (“STI”) structure may be formed in the substrate. Generally, an STI is defined by sidewalls and a bottom and comprises dielectric material such as silicon oxide (SiO₂), silicon nitride (Si₃N₄), silicon oxynitride (SiOₓN_{y}), or any combination thereof.

The substrate may include any underlying material or materials upon which a device, a circuit, an epitaxial layer, or a semiconductor may be formed. Generally, a substrate may be used to define the layer or layers that underlie a semiconductor device or even forms the base layer of a semiconductor device. Without intending to be limiting, the substrate may include one or any combination of silicon, doped silicon, germanium, silicon germanium, semiconductor compounds, or other semiconductor materials.

The dielectric layers for the film stack may comprise any suitable dielectric material, such as silicon oxide (SiO₂), silicon nitride (Si₃N₄), silicon oxynitride (SiOₓN_{y}), or any combination thereof. For instance, the oxide hard mask layer, the interpoly dielectric layer, and the tunnel oxide layer may comprise silicon oxide (SiO₂), silicon nitride (Si₃N₄), silicon oxynitride (SiOₓN_{y}), or any combination thereof. In certain embodiments, one or more dielectric layers may comprise an oxide-nitride-oxide (ONO) layer. One or more dielectric layers may be formed by any suitable deposition process, such as chemical vapor deposition (CVD) or spin-on dielectric processing. In certain embodiments, one or more dielectric layers may be grown on the substrate.

In some embodiments, the conductive layers may comprise polysilicon. For instance, the control gate and floating gate may comprise polysilicon. One or more conductive layers may be formed by any suitable process, such as CVD or spin coating.

The embodiment illustrated in FIG. 1(b) includes pads 210, word lines 220, and transistors 230. FIG. 1(c) illustrates an enlarged view of two adjacent word line pads 310.

As shown in FIG. 1(c), the two adjacent pads 310 have a space between the two pads. In certain embodiments of the invention, such as that illustrated in FIG. 1, the space between adjacent pads may have a width represented by a. For instance, FIG. 1(c) illustrates an embodiment of width a. In certain embodiments, the space between adjacent pads may also have a width represented by b. For instance, FIG. 1(c) illustrates an embodiment of width b. In some embodiments, a word line pad may have a first width located opposite of the connecting word line and a second width located adjacent to the connecting word line. For instance, in FIG. 1(c), the first width located opposite to the connecting word line is represented by a, while the second width located adjacent to the connecting word line is represented by b. In certain embodiments, the first width located opposite of the word line may be smaller than the second width located adjacent to the word line. In some embodiments, the second width located adjacent to the word line may be about 1.5 to 3.0 times larger than the first width located opposite of the word line. For instance, the second width may be about 1.6, 1.7, 1.8, 1.9, 2.0, 2.1, 2.2, 2.3, 2.4, 2.5, 2.6, 2.7, 2.8, or 2.9 times larger than the first width opposite to the word line.

As shown in FIG. 1, the space between the adjacent pads has two widths, a width a, and a width b where width b is equal to about 1.5 to 3.0 times width a. In some embodiments of the present invention, more than one set of pads have a space with two widths, where the first width opposite of the connecting word line is smaller than the second width adjacent to the connecting word line. For instance, a plurality of adjacent pads may have the disclosed space with two widths where one width is smaller than the second width. The plurality of pads may have spaces between adjacent pads with two widths where the second width adjacent connecting word lines is about 1.5 to 3.0 times the first width opposite to the connecting word lines. As shown in FIG. 1, adjacent word line pads may be mirror images of each other. That is, along the axis between the two pads, the pads may be mirror images or reflections of each other. The dimensions of the pads may be the same. For instance, a space may be formed between the pads that is in the shape of a pendulum creating adjacent pads that are mirror images. In some embodiments, the word line pads are mirror images across the Y2 axis. FIG. 1 illustrates an embodiment where the word line pads are mirror images across the Y2 axis.

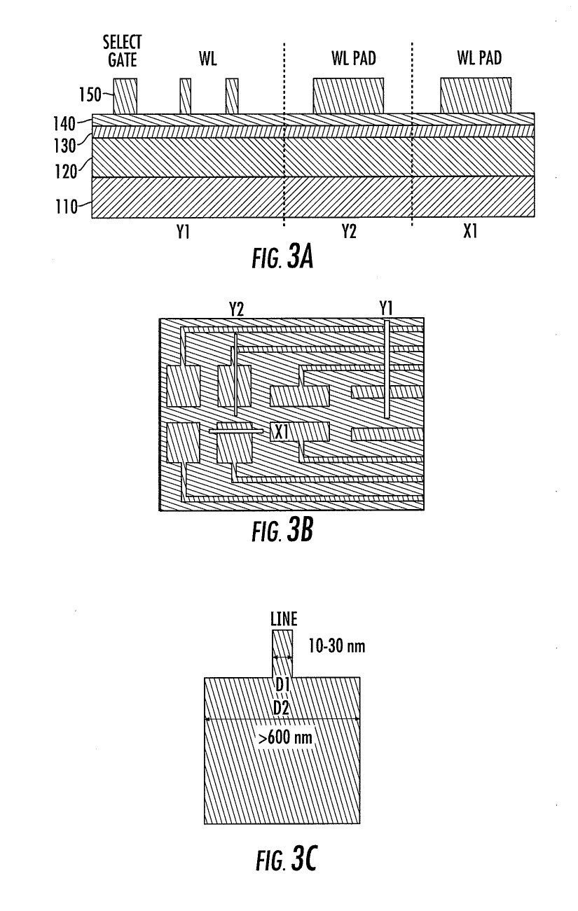

In certain embodiments of the present invention, the semiconductor device may be formed from a structure comprising a substrate and a film stack. In the embodiment illustrated in FIG. 2, the structure comprises a silicon substrate 110, a word line film stack 120, a first hard mask layer 130, a second hard mask layer 140, and an advanced patterning film (“APF”) core material 150. While FIG. 2 provides specific exemplary materials for each layer, the present invention is not so limited and can be used with any suitable material. For instance, the substrate may comprise materials such as those previously described (e.g., silicon, doped silicon, germanium, silicon germanium, semiconductor compounds, or other semiconductor materials). The film stack may be any film stack desired in the final structure and may be formed along the substrate by any suitable process. Exemplary film stacks have been discussed above.

In certain embodiments, one or more hard mask layers may be formed on the film stack. The one or more hard mask layers may be comprised of any suitable material to allow for self-aligned patterning. For instance, the hard mask layer may be comprised of silicon nitride, polysilicon, any other hard mask layer, or combinations thereof. The embodiment of FIG. 2 illustrates two hard mask layers, a first hard mask layer 130 and a second hard mask layer 140. In this embodiment, the first hard mask layer 130 comprises polysilicon and the second hard mask layer 140 comprises silicon nitride. The hard mask layers may be formed by any suitable process.

In some embodiments, a first core material may be formed on the one or more hard mask layers. The core material may be any suitable material for patterning such as APF, polysilicon, any other material suitable as the core material for self-aligned double patterning, and combinations thereof.

FIG. 2 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 2(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 2(b). An enlarged view of where adjacent word line pads may be formed is provided in FIG. 2(c).

FIG. 2 illustrates cross-sectional views of a semiconductor device after applying a photo resist to the device in accordance with embodiments of the present invention. The photo resist may be any suitable photo resist that allows the patterning of the underlying core material. In certain embodiments, it may be desirable to form a patterned core layer. To form this patterned core, in some embodiments, a photo resist may be applied to the device and with a single mask may form a pattern over the core material in both the array and periphery regions. As shown in FIG. 2, in certain embodiments, the photo resist may be applied to form a pattern over the core material. In certain embodiments, the photo resist may be applied to form at least one pad pattern with certain dimensions, such as that illustrated in FIG. 2(c). For instance, in certain embodiments, it may be desirable to have a pad pattern connected to a word line pattern in the middle of the pad pattern. In some embodiments, the word line pattern may connect to the pad pattern at a point on the pad pattern where the distance to each edge is equal. For example, FIG. 2(c) illustrates the word line pattern connecting to the pad pattern in the middle of the pad pattern such that distance A from the point of connection to either edge is the same (e.g., A=A).

In certain embodiments, it may be desirable to form a word line of certain dimensions. In some embodiments, the word line pattern may have a width D1. For instance, the word line pattern may have a width of about 5 to 50 nm, such as about 10 to 40 nm, or about 10 to 30 nm. FIG. 2 illustrates an embodiment where word line pattern has a width D1 of about 10 to 30 nm.

In some embodiments, it may be desirable to form a pad of a certain width. For instance, the pad pattern may have a width D2 greater than about 200 nm wide, such as greater than about 400 nm, or greater than about 600 nm. FIG. 2 illustrates an embodiment where the pad pattern has a width D2 greater than about 600 nm.

Using the photo resist, the device may be etched. FIG. 3 illustrates cross-sectional views of a semiconductor device after etching a patterned core layer in the device in accordance with embodiments of the present invention. FIG. 3 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 3(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 3(b). An enlarged view of where adjacent word line pads may be formed is provided in FIG. 3(c).

FIG. 3 illustrates the etching of the core material to provide a pattern on the substrate. The photo resist may protect certain desired areas of the core material from etching such that a pattern is formed. Any suitable etching process may be used to etch the applicable core material, and the photo resist may be removed by any known process to leave the core material in the desired pattern. As shown in the embodiment of FIG. 3, the core material 150 remaining on the underlying hard mask layer forms at least one pad pattern with a width greater than about 600 nm and with a connecting word line pattern about 10-30 nm wide. The width of the pad pattern may be about greater than 200 nm, greater than about 400 nm, or greater than about 600 nm. The width of the connecting word line pattern may be about 5 to 500 nm, such as about 10 to 40 nm, or about 10 to 30 nm.

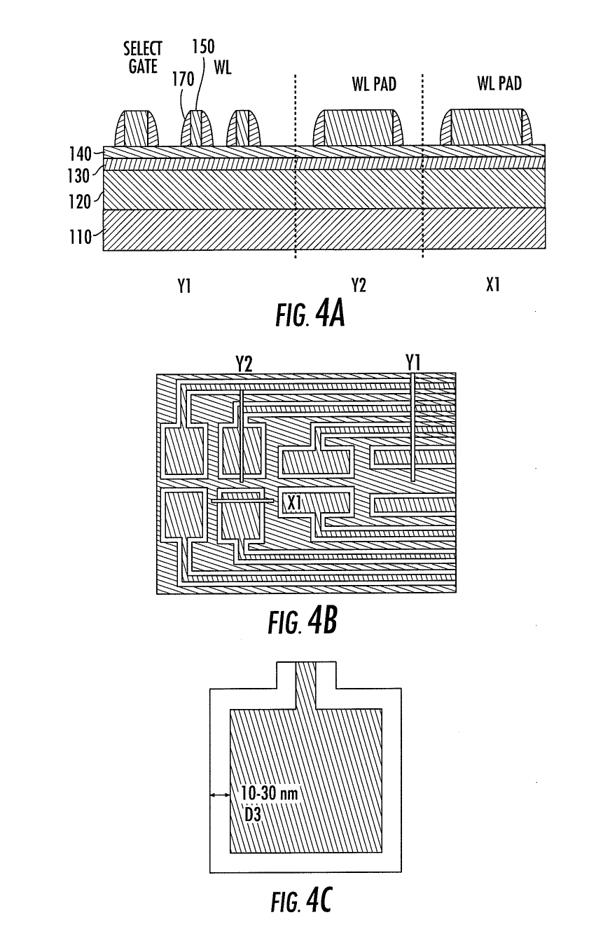

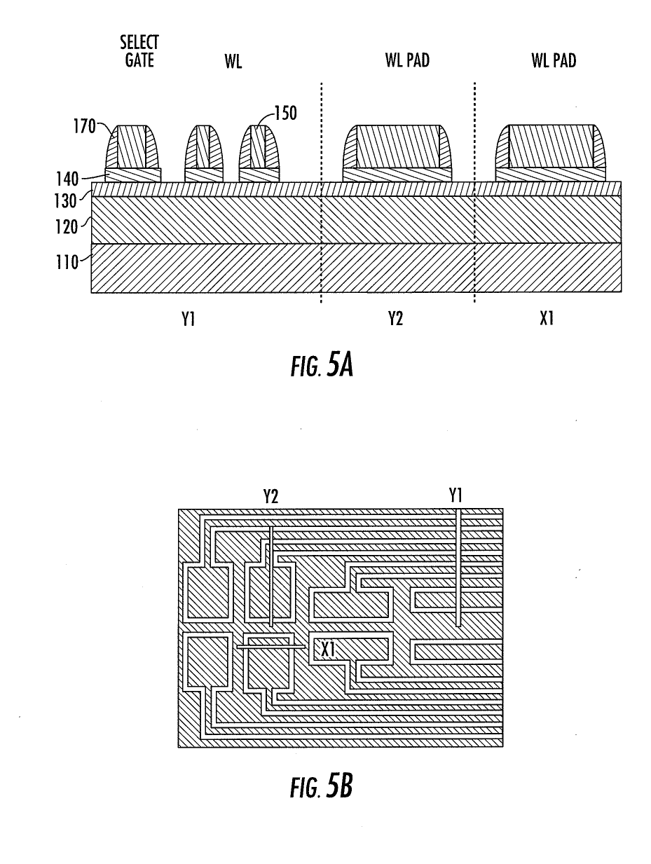

In certain embodiments, spacers may be formed along sidewalls of the patterned second core layer. FIG. 4 illustrates cross-sectional views of a semiconductor device after forming spacers 170 along the sidewalls of the patterned core layer 150 in the device in accordance with embodiments of the present invention. FIG. 4 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 4(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 4(b). An enlarged view of where adjacent word line pads may be formed is provided in FIG. 4(c).

In certain embodiments, the spacer material may be deposited or formed on the semiconductor device. The spacer material may be disposed along the surface of the semiconductor device and subjected to a partial etch to form spacers, such as the spacers 170 of FIG. 4, disposed along the sidewalls of the patterned core material, such as the patterned core material 150 of FIG. 4. Trenches, or open areas, may be formed between spacers.

In certain embodiments, the spacer material may comprise any suitable material for forming spacers for self-aligned patterning. For instance, in some embodiments, low-temperature oxide may be deposited on the device and etched to form spacers along the sidewalls of the patterned core. In the embodiment illustrated in FIG. 4, the spacers 170 comprise low-temperature oxide. In certain embodiments, spacers may be formed of a desired thickness, which may be represented by D3 as shown in FIG. 4(c). The spacer material may be any suitable thickness, such as from 5 to 50 nm, 10 to 40 nm, or from 10 to 30 nm wide. As shown in FIG. 4(c), in certain embodiments, the spacer material may form spacers of 10 to 30 nm wide along the patterned core material.

In some embodiments, a second hard mask layer may be etched along the device. FIG. 5 illustrates cross-sectional views of a semiconductor device after etching the second hard mask layer 140. FIG. 5 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 5(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 5(b).

In certain embodiments of the present invention, the second hard mask layer may be etched along the uncovered areas, that is, the areas not covered by the spacers and the core material. In the embodiment of FIG. 5, the second hard mask layer 140 comprises silicon nitride and is etched in areas not covered by the spacers 170 and APF core material 150. The hard mask layer may be etched or removed by any suitable process that allows the removal of the second hard mask layer while leaving the first hard mask layer on the substrate.

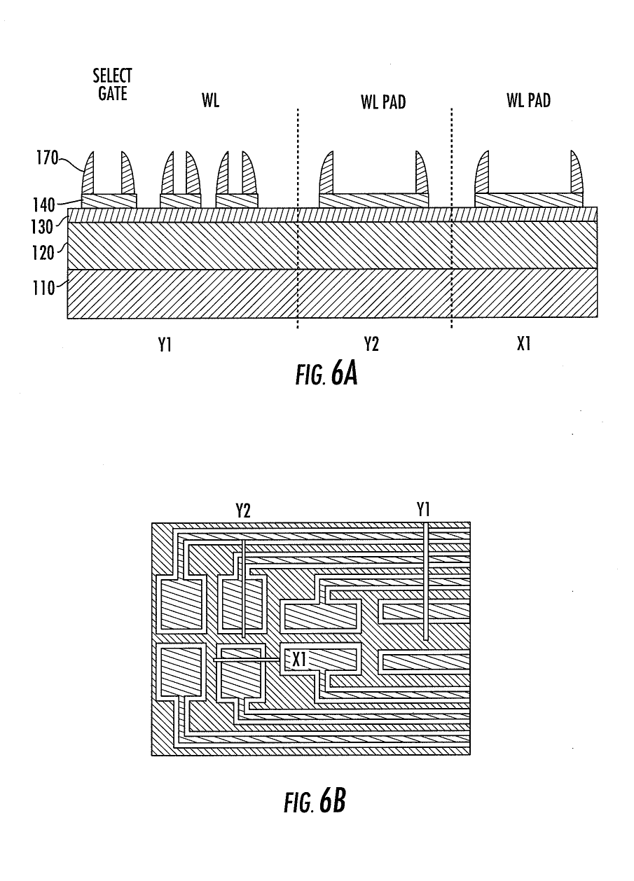

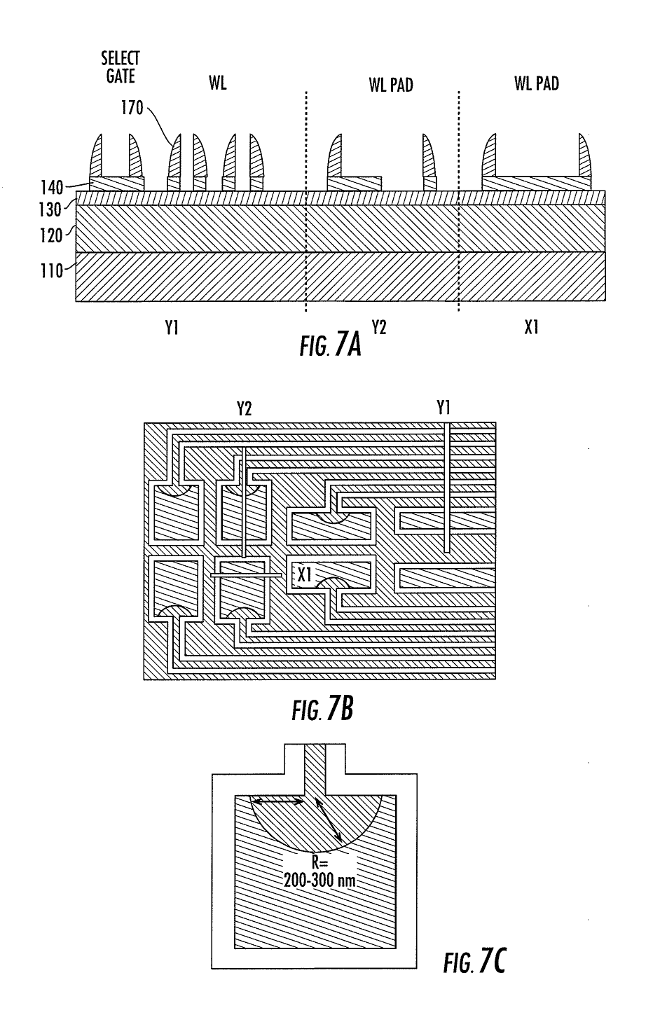

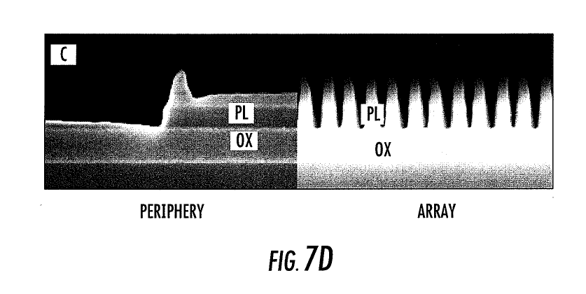

In some embodiments, the patterned core layer may be removed from the semiconductor device after etching a second hard mask layer. FIG. 6 illustrates cross-sectional views of a semiconductor device after removing core material from the semiconductor device in accordance with embodiments of the present invention. FIG. 6 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 6(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 6(b).

The patterned core layer may be removed by any suitable process such as dry or wet strip, leaving spacers disposed along the substrate. The spacers disposed along the substrate may provide an outline for subsequent etching. As shown in FIG. 6, the removal of the core material 150 provides open spaces between spacers 170 and over the second hard mask layer 140.

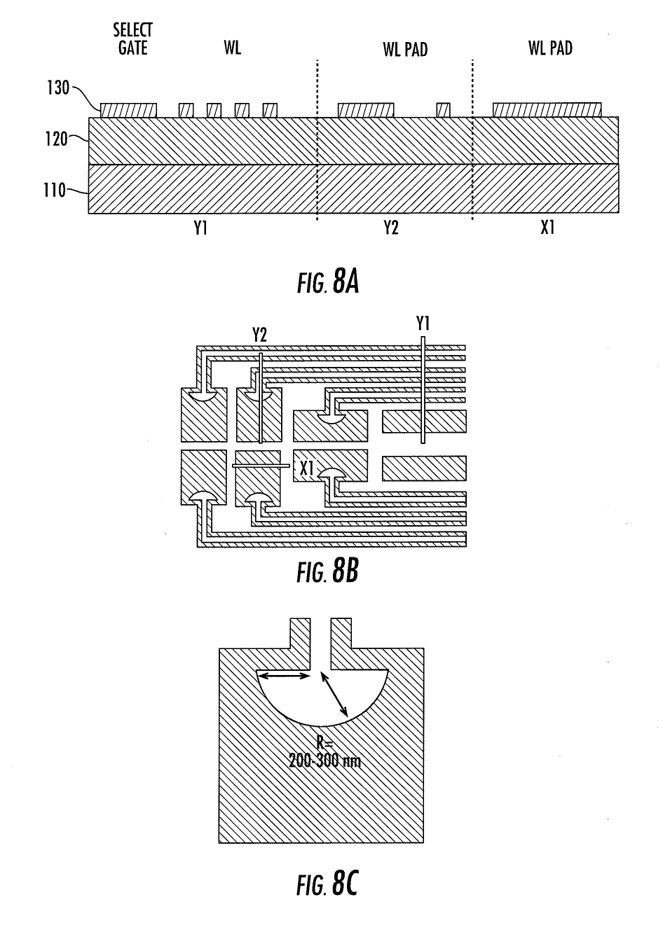

In certain embodiments of the present invention, portions of the second hard mask layer may be removed. FIGS. 7(a) to 7(c) illustrate cross-sectional views of a semiconductor device after removing certain areas of the first hard mask layer. FIGS. 7(a) to 7(c) provide cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 7(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 7(b). An enlarged view of where adjacent word line pads may be formed is provided in FIG. 7(c).

In certain embodiments, only certain areas of the second hard mask layer may be removed. In certain embodiments, prior to removing portions of the second hard mask layer, a polymer may be loaded onto the device. In certain areas, such as smaller narrow areas, less polymer may be loaded, while in other areas, such as larger open areas, more polymer may accumulate in the area. Subsequent etching may remove more hard mask material in areas with less polymer, while leaving hard mask material in areas with more polymer. For instance, as shown in FIG. 7, the second hard mask material 140 may be removed from narrow spaces between spacers 170 (see e.g., the Y1 cross section, “WL” in FIG. 7(a)), while the second hard mask material 140 may remain in wider areas between spacers 170 (see e.g., the X1 cross section, “WL PAD” in FIG. 7(a)). The different removal amounts may be attributed to the “loading effect” of the polymer. For instance, in certain embodiments, due to more polymer being loaded in larger areas, the second hard mask material between closely spaced spacers may be removed while the second hard mask material between further apart spacers may remain. As more polymer may be loaded between farther apart spacers, such as those in the periphery region, the second hard mask material may not be removed in these areas during subsequent etching. Less or no polymer material may be loaded between closely spaced spacers, such as those in the array region, such that the second hard mask material in such locations may be removed.

Thus, in certain embodiments, when etching, the hard mask layer may be removed in the smaller areas and not in the larger areas. As shown in FIGS. 7(a) and 7(b), the second hard mask layer 140 is removed between spacers 170 in word line patterns, as these spacers are located close together. As also shown in FIGS. 7(a) and 7(b), along the X1 axis, the second hard mask layer 140 is not removed between spacers 170. More polymer has deposited in this large area between spacers preventing the etching of the second hard mask layer.

In some embodiments, small or narrow areas may come in contact with larger open areas. For instance, along the Y2 axis, a portion of the second hard mask layer has been removed while a portion of the layer remains on the substrate. The Y2 axis is located along the entrance of the connecting word line pattern to the pad pattern. Without intending to be bound by theory, due to the connection of the small areas of the word line pattern and the larger areas that form the pad pattern, some part of the second hard mask layer on the pad pattern may be removed. As noted previously, this area at the connection of the word lines to the pads may be referred to as the boundary area.

In certain embodiments, the removal of the second hard mask material in the boundary area may form a pattern. For instance, as shown in FIG. 7(c), the loading effect may create a pattern in the pad pattern. This pattern may be any shape such as the semicircle or pendulum-shape illustrated in FIG. 7(c). In other embodiments, the loading effect may create a different shape depending on the configuration of the components. In some embodiments, the shape may have a dimension such as radius R illustrated in FIG. 7(c). In certain embodiments, this dimension may be about 50 to 500 nm, such as about 100 to 400 nm, or about 200 to 300 nm. For instance, in the embodiment illustrated in FIG. 7(c), a semicircle may be formed in the pad pattern with a radius of about 200 to 300 nm.

In certain embodiments, it may be desirable to form a boundary circle with a radius of about 200 to about 300 nm to allow the subsequent etching of the film stack. With a larger radius of the pendulum, the pad may have a larger window for subsequent etching. Without intending to be bound by theory, by providing a larger window with the formation of the pendulum, or other shape, in the boundary area, the subsequent etching of individual pads in the pad pattern may be made easier. In certain embodiments, the etching of the second hard mask material may be manipulated to modify the resulting pattern formed in the boundary area. When etching, various etching gases may be used, such as CH₂F₂, C₄F₈, C₄F₆, C₅F₈, CH₃F, CHF₃, and combinations thereof, and at various gas flow rates, such as from 10 to 100 sccm. By adjusting the etching gas composition and the gas flow rate, desired patterns may be formed in the boundary area, such as a semicircle with a radius of 200 to 300 nm.

FIG. 7(d) provides a profile of the array and periphery regions of a semiconductor device after removing portions of the second hard mask layer. As shown in FIG. 7(d), the second hard mask layer is not removed from the areas between spacers in the periphery region. As also shown in FIG. 7(d), the second hard mask layer is removed from areas between spacers in the array region.

In certain embodiments, it may be desirable to etch the second hard mask layer to provide a pattern for subsequent etching of the film stack. FIG. 8 illustrates cross-sectional views of a semiconductor device after etching the first hard mask layer in accordance with embodiments of the present invention. FIG. 8 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 8(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 8(b). An enlarged view of where adjacent word line pads may be formed is provided in FIG. 8(c).

As shown in FIG. 8, those areas of the first hard mask layer 130 not covered by the second hard mask layer 140 may be removed leaving a pattern on the substrate for subsequent etching of the film stack 120. As certain areas of the second hard mask layer were removed in the pad pattern due to the polymer loading effect, the shape formed by this removal may be carried over to the first hard mask layer. One pattern may be seen in FIG. 8(c). The radius of the semicircle in the embodiment of FIG. 8 is between 200 to 300 nm. The radius of the semicircle or the size of any other shape formed in the pad pattern due to the polymer loading effect in the previous step may be of any size so long as a window may be formed for subsequent etching of the film stack. The present inventors have found that a radius of 200 to 300 nm provides a sufficiently large window for subsequent etching of the film stack.

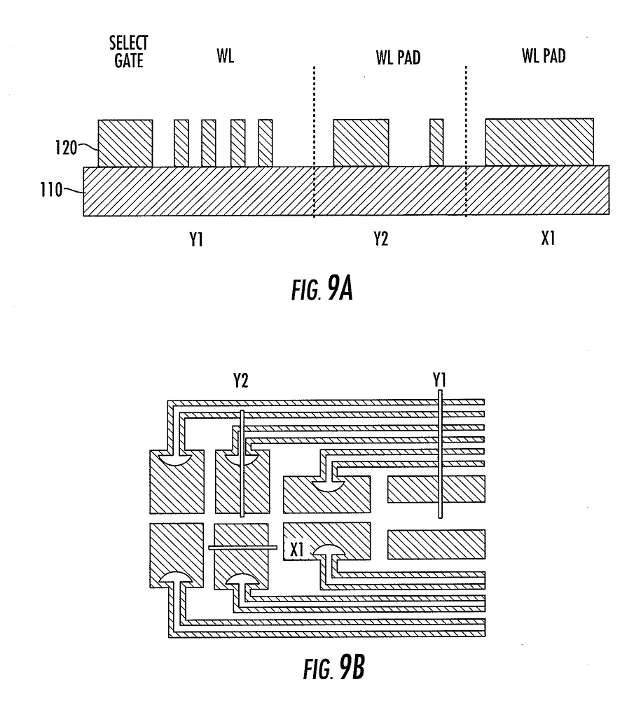

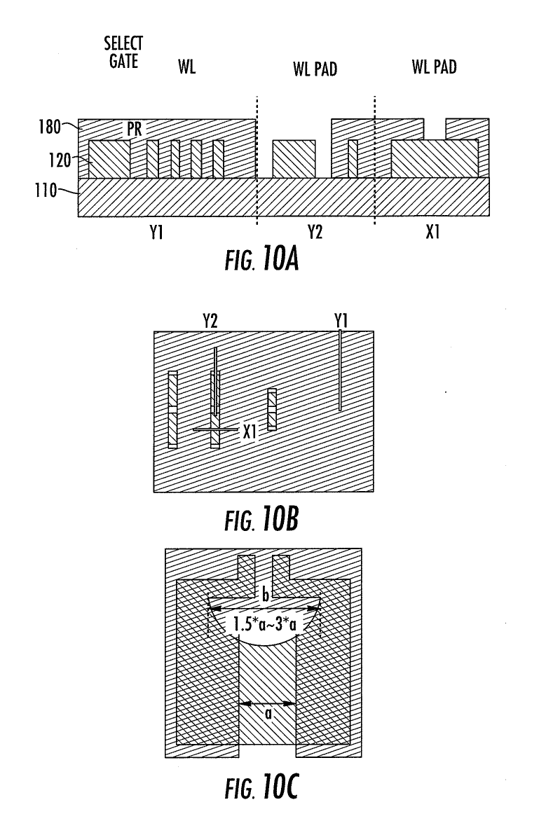

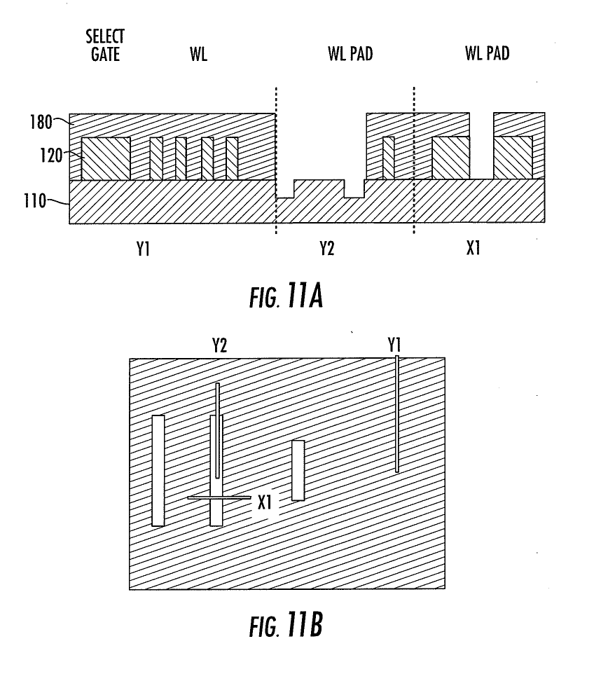

In certain embodiments, it may be desirable to etch the film stack to form desired features in the device. FIG. 9 illustrates cross-sectional views of a semiconductor device after etching the film stack in accordance with embodiments of the present invention. FIG. 9 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 9(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 9(b).

Based on the pattern formed by the first hard mask layer, the film stack may be etched to define the array region and the periphery region. As shown in FIG. 9(b), word lines and word line pads may be defined by etching in the array and periphery regions.

The film stack may be etched with any suitable process to form the desired features. In certain embodiments, the pattern formed after removing portions of the second hard mask layer may be transferred to the film stack. For instance, as shown in FIG. 9(b), the pattern formed in the pad pattern (e.g., semicircles formed in the pad pattern) may be transferred to the film stack forming pads comprising such pattern. In some embodiments, such as that illustrated in FIG. 9(b), film stack may be etched to form a semicircle in one or more pads. One or more semicircles may have any suitable dimensions. For instance, one or more semicircles may have a radius of about 50 to 500 nm, such as about 100 to 400 nm, or about 200 to 300 nm.

In some embodiments, the pads formed by etching the film stack may be connected to more than one word line. That is, in some embodiments, a single pad may be connected to more than one word line. In such embodiments, it may be desirable to further etch the pad such that a pad is connected to only one word line. If a pad is connected to more than one word line, the pad may short circuit resulting in failure of the device. In some embodiments, a photo resist may be applied to the device such that portions of pads connected to multiple word lines may be exposed for subsequent etching. The portions unprotected may be etched to separate pads and provide a device where each pad is only connected to a single word line.

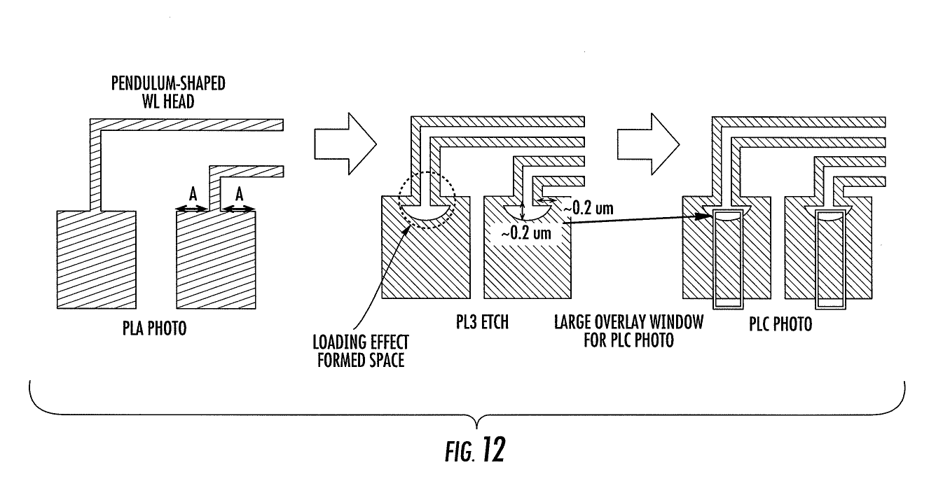

FIG. 10 illustrates cross-sectional views of a semiconductor device after applying a photo resist over the patterned film stack in accordance with embodiments of the present invention. FIG. 10 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 10(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 10(b). An enlarged view of where adjacent word line pads may be formed is provided in FIG. 10(c).

After defining the array and periphery regions, the word line pads may need further etching to form adjacent pads. A photo resist may be applied over the film stack to separate adjacent word line pads. The photo resist may comprise any suitable photo resist to allow the removal of uncovered underlying regions by subsequent etching. It may be desirable to form adjacent word line pads with a certain defined space. For instance, as shown in FIG. 10(c), a photo resist may be formed over the patterned film stack to allow for formation of a space between adjacent word line pads with a width such as width “a.” In certain embodiments, it may be preferable to have the diameter of the etched pattern in the boundary area to be equal to 1.5 to 3 times the space “a” between adjacent word line pads. Without intending to be bound by theory, by forming a pattern in the boundary area that is about 1.5 to 3 times as wide as the distance between adjacent word line pads, a window of sufficient size for subsequent etching to form adjacent word line pads can be made. The width may be any suitable width to allow for separation of the pad and to provide a device where each pad is only connected to a single word line.

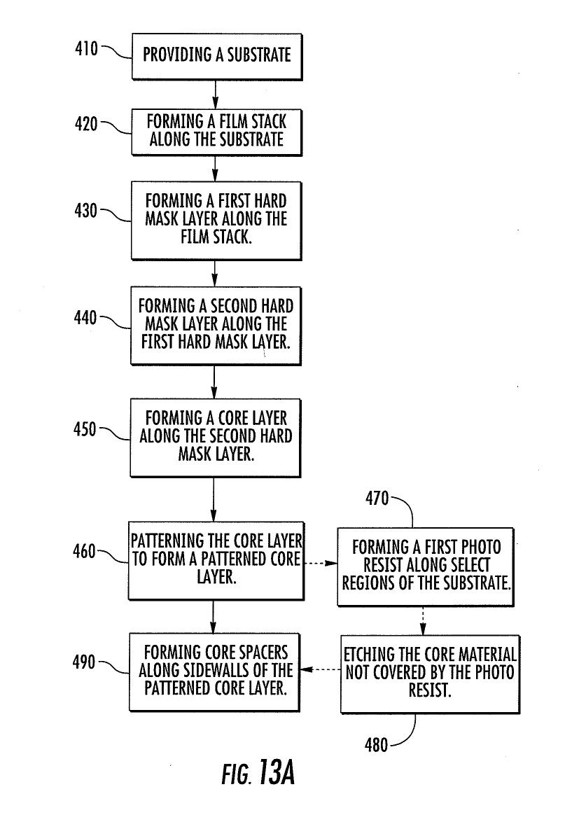

FIG. 11 illustrates as semiconductor device after etching to form adjacent word line pads in accordance with embodiments of the present invention. FIG. 11 provides cross sections of the semiconductor device in the array and periphery regions. The array cross section is represented by the Y1 axis and the periphery cross section is represented by the X1 axis. The connection between the array and periphery regions is represented by the Y2 axis. The X1 axis lies across a pad pattern. The cross sections are illustrated in FIG. 11(a) with identifying markings showing the Select Gate, Word Line (“WL”), Word Line PAD Connection (“WL PAD”), and Word Line PAD (“WL PAD”). An overview of the semiconductor illustrating the various cross sections is provided in FIG. 11(b).

As shown in FIG. 11, by applying a photo resist over the remaining portions of the semiconductor device, the areas that need to be etched to separate the word line pads may be etched and removed. In certain embodiments, after the desired areas are etched and the photo resist is removed, a semiconductor device such as that illustrated in FIG. 1 may be formed.

FIG. 12 illustrates the formation of a semicircle or pendulum-shaped area in word line pads in accordance with embodiments of the present invention. In certain embodiments of the invention, pad patterns are formed connected to word line patterns at the middle of the pad pattern. As shown in the first image of FIG. 12, the word line pattern connects to the word line pad at the middle of the pad such that the distance from the connection point to the end of the pad pattern (referred to as “A”) is the same on either side of the connection point. Without intending to be bound by theory, the inventors have found that by placing the connection point in the middle of the word line, the loading effect seen in etching portions of the second hard mask layer may form a pendulum-shaped area in the boundary area of the pad pattern. As shown in the second image of FIG. 12, the loading effect creates a pendulum-shaped area, or a semicircle, centered by the connection point of the word line pattern to the pad pattern. In certain embodiments, such as that illustrated by FIG. 12, the radius of the pendulum or the shape formed by the loading effect when etching the second hard mask layer may be about 0.2 μm. The formation of the pattern in the boundary area creates a large overlay window for separating the pad into two separate pads such that each pad has a single connection point to a word line. The formation of the pattern in the boundary area makes subsequent etching of the film stack easier. Without intending to be bound by theory, the present inventors have found that by using this layout of the semiconductor device and methods of forming this layout, patterning of the array and periphery regions can be combined to provide a cheaper and more efficient process of forming suitable semiconductor devices.

An aspect of the invention provides a semiconductor fabricated using the processes or methods for fabricating a semiconductor as disclosed herein. In certain other embodiments of the invention, a semiconductor device may be fabricated using any combination of the method steps as described herein. Further, any manufacturing process known to those having ordinary skill in the art having the benefit of this disclosure may be used to manufacture the semiconductor devices in accordance with embodiments of the present invention.

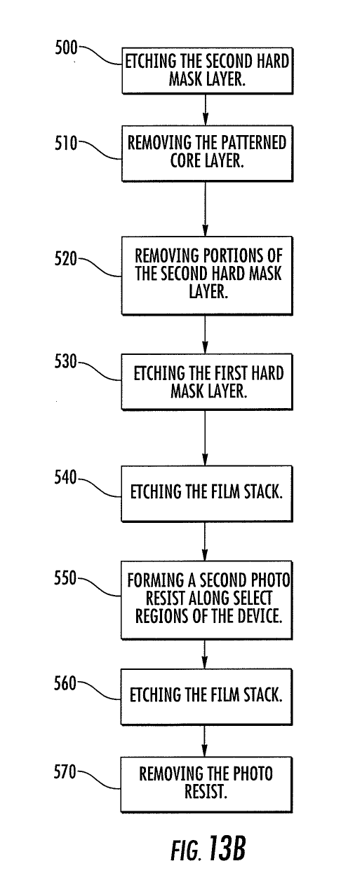

FIGS. 13(a) and 13(b) provides a flow chart detailing a method of forming a semiconductor device in accordance with embodiments of the present invention. In certain embodiments, a method for manufacturing a semiconductor device according to the present invention may comprise, providing a substrate 410 and forming a film stack along the substrate 420. In some embodiments, the method may further comprise forming a first hard mask layer along the film stack 430, forming a second hard mask layer along the first hard mask layer 440, and forming a core layer along the second hard mask layer 450. The method may further comprise patterning the core layer to form a patterned core layer 460. In some embodiments, when patterning the core layer to form a patterned core layer, the method may comprise forming a first photo resist along select regions of the substrate 470 and etching the core material not covered by the photo resist 480. In some embodiments, such as that illustrated in FIG. 13(a), the method of manufacturing a semiconductor device according to the present invention may comprise forming core spacers along sidewalls of the patterned core layer 490. As shown in FIG. 13(b), the method may further comprise etching the second hard mask layer 500, removing the patterned core layer 510, and removing portions of the second hard mask layer 520. In some embodiments, the method may further comprise etching the first hard mask layer 530 and etching the film stack 540. In yet additional embodiments, the method may further comprise forming a second photo resist along select regions of the device 550, etching the film stack 560, and removing the photo resist 570. Methods of the present invention may include various combinations of the steps illustrated in FIGS. 13(a) and 13(b).

Any of the processes, methods, or techniques as described herein may be used to accomplish any of these steps of the inventive method. Certain of the steps generally described above in the method may themselves comprise other sub-steps that have not necessarily been identified. Such additional steps are understood by a person of ordinary skill in the art having the benefit of this disclosure.

The present invention may be used for the fabrication of any memory device. For instance, the method of the present invention may be applied to the fabrication of any non-volatile memory device, such as NAND flash memory devices, NOR flash memory devices, logic device, or any other device where self-aligned multiple patterning is used.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A semiconductor device comprising:
a substrate;
a first word line pad formed on the substrate; and
a second word line pad formed on the substrate,
wherein a space is located between the first word line pad and the second word line pad, the space comprising a substantially rectangular region having a first width represented by a and a substantially semicircular region having a second width represented by b integrated with the substantially rectangular region, and
wherein the width b is from about 1.5 to about 3.0 times the width a, and a radius of the substantially semicircular region is from about 50 nm to about 500 nm.

2. The semiconductor device of claim 1, wherein the width b is located closer to a word line than the width a and wherein the word line connects to the first word line pad or the second word line pad.

3. (canceled)

4. The semiconductor device of claim 1, wherein the width b is about 1.5 times the width a.

5. The semiconductor device of claim 1, wherein the width b is about 3.0 times the width a.

6. The semiconductor device of claim 1, wherein the first word line pad comprises a first pad width adjacent to a word line and a second pad width opposite the word line, wherein the first pad width is not equal to the second pad width, and wherein the word line connect to the first word line pad.

7. The semiconductor device of claim 6, wherein the second word line pad comprises a first width of the second word line pad adjacent to a word line and a second width of the second word line pad opposite the word line and wherein the first width of the second word line pad is smaller than the second width of the second word line pad.

8-20. (canceled)

21. The semiconductor device of claim 1, wherein the second width b is equal to double the radius of the substantially semicircular region.
